(19) United States
(12) Patent Application Publication
(10) Pub. No.: US 2016/0163708 A1
(43) Pub. Date: Jun. 9, 2016

(54) SEMICONDUCTOR DEVICE INCLUDING TRANSISTORS

(71) Applicant: SAMSUNG ELECTRONICS CO., LTD., SUWON-SI (KR)

(72) Inventors: SUNG-HO JANG, SEOUL (KR); SATORU YAMADA, SEOUL (KR); JUN-HEE LIM, SEOUL (KR); JU-YEON JANG, HWASEONG-SI (KR); KYOUNG-HO JUNG, SUWON-SI (KR); JOON HAN, HWASEONG-SI (KR)

(21) Appl. No.: 14/957,169

(22) Filed: Dec. 2, 2015

(30) Foreign Application Priority Data
Dec. 4, 2014 (KR) 10-2014-0173231

(51) Int. Cl. H01L 27/108; G11C 11/408; G11C 11/4091; H01L 27/02; H01L 27/092

(52) U.S. Cl. CPC H01L 27/108; H01L 27/0207; H01L 27/0922; G11C 11/4091; G11C 11/4085; G11C 11/4087

(57) ABSTRACT

A semiconductor device includes a semiconductor substrate having a first transistor region and a second transistor region, a first MOSFET including a first gate insulating layer structure and a first gate electrode structure, and a second MOSFET including a group IV compound semiconductor layer, a second gate insulating layer structure, and a second gate electrode structure. The first gate insulating layer structure and the first gate electrode structure are disposed on the first transistor region of the semiconductor substrate. The group IV compound semiconductor layer is disposed on the second transistor region of the semiconductor substrate, and the second gate insulating layer and the second gate electrode structure are disposed on the group IV compound semiconductor layer. Each of the first and second gate insulating layer structures includes a high-k dielectric (insulating) layer.

### PRIORITY STATEMENT

This application claims the benefit of Korean Patent Application No. 10-2014-0173231, filed on Dec. 4, 2014, in the Korean Intellectual Property Office, the disclosure of which is hereby incorporated by reference in its entirety.

### BACKGROUND

The inventive concept relates to semiconductor devices. More particularly, the inventive concept relates to a semiconductor device including metal-oxide-semiconductor field effect transistors (MOSFETs).

Semiconductor devices, including semiconductor-based transistors, are prevalent in today's electronic products. As the electronics industry has grown dramatically, users' demands for smaller and lighter electronic products have increased. Accordingly, the semiconductor devices of electronic products are required to have higher degrees of integration and improved operating speeds. However, when transistors of semiconductor devices are scaled down and the operating speed of the scaled-down transistors is increased, leakage current of the transistors increases in a stand-by state and thus, the power consumption of the devices tends to increase.

### SUMMARY

According to an aspect of the inventive concept, there is provided a semiconductor device including: a semiconductor substrate having a first transistor region and a second transistor region, a first metal-oxide-semiconductor field effect transistor (MOSFET) comprising a first gate insulating layer structure and a first gate electrode structure, and a second MOSFET comprising a group IV compound semiconductor layer, a second gate insulating layer structure, and a second gate electrode structure. The first gate insulating layer structure and the first gate electrode structure are disposed on the first transistor region of the semiconductor substrate. The group IV compound semiconductor layer is disposed on the second transistor region of the semiconductor substrate, and the second gate insulating layer structure and the second gate electrode structure are disposed on the group IV compound semiconductor layer. Furthermore, each of the first and second gate insulating layer structures comprises a high-k dielectric layer.

According to an aspect of the inventive concept, there is provided a semiconductor device including: a semiconductor substrate having a cell array region and a peripheral/core region, a cell transistor at the cell array region, a bit line electrode electrically connected to the cell transistor, a first metal-oxide-semiconductor field effect transistor (MOSFET) comprising a first gate insulating layer structure and a first gate electrode structure, and a second MOSFET comprising a group IV compound semiconductor layer, a second gate insulating layer structure, and a second gate electrode structure. The first gate insulating layer structure is disposed on the peripheral/core region of the semiconductor substrate, and the first gate electrode structure is disposed on the first gate insulating structure. The group IV compound semiconductor layer is disposed on the peripheral/core region of the semiconductor substrate, and the second gate insulating layer structure and the second gate electrode structure are disposed on the group IV compound semiconductor layer. Furthermore, each of the first and second gate insulating layer structures comprises a high-k dielectric layer, and the bit line electrode comprises the same material as at least a portion of each of the first and second gate electrode structures.

According to an aspect of the inventive concept, there is provided a semiconductor device including:

a first complementary metal-oxide-semiconductor field effect transistor (CMOS), and a second CMOS and in which the (PMOS) of the first CMOS has a channel region of first semiconductor material, a first gate insulating structure of dielectric material disposed directly on the channel region, and a first electrically conductive gate structure disposed directly on the first gate insulating structure, the PMOS of the second CMOS has a channel region of second semiconductor material in which holes have greater mobility than the holes have in the first semiconductor material constituting the channel region of the first PMOS, a second gate insulating structure of dielectric material disposed directly on the channel region of the second PMOS, and a second electrically conductive gate electrode structure disposed directly on the second gate insulating structure, the first gate insulating structure is thicker than the second gate insulating structure, and the operating voltage of the first CMOS is higher than that of the second CMOS.

### BRIEF DESCRIPTION OF THE DRAWINGS

The inventive concept will be more clearly understood from the following detailed description of representative embodiments of the inventive concept taken in conjunction with the accompanying drawings in which:

FIG. lA is an equivalent circuit diagram of a representative embodiment of a complementary metal-oxide-semiconductor (CMOS) device according to the inventive concept;

FIG. 1B is a plan view of the CMOS device illustrated in FIG. 1A;

FIGS. 2 through 9 are cross-sectional views of a semiconductor device during the course of its manufacture and together illustrate a representative embodiment of a method of manufacturing a semiconductor device, according to the inventive concept, wherein

FIG. 2 illustrates a process of formed a device isolation layer in a semiconductor substrate,

FIG. 3 illustrates a process of forming a group IV compound semiconductor layer,

FIG. 4 illustrates a process of forming a first dielectric layer,

FIG. 5 illustrates a process of forming a second dielectric layer, a high-k insulating layer, and a first metal gate material layer,

FIG. 6 illustrates a process of forming a second metal gate material layer,

FIG. 7 illustrates a process of forming a first conductive material layer,

FIG. 8 illustrates a process of forming a direct contact plug, and

FIG. 9 illustrates a process of forming a second conductive material layer and a capping material layer;

FIG. 10 is a cross-sectional view of a representative embodiment of a semiconductor device according to the inventive concept;

FIG. 11 is a cross-sectional view of another embodiment of a semiconductor device according to the inventive concept;

FIG. 12 is a cross-sectional view of still another embodiment of a semiconductor device according to the inventive concept;

FIG. 13 is a cross-sectional view of yet another embodiment of a semiconductor device according to the inventive concept;

FIG. 14 is a block diagram of representative embodiments of a semiconductor device according to the inventive concept;

FIG. 15 is a diagram of a layout of an example of a memory core unit of a semiconductor device according to the inventive concept;

FIG. 16 is a diagram of a layout of a memory cell array block of the memory core unit;

FIG. 17 is a plan view of a memory module including a semiconductor device according to the inventive concept;

FIG. 18 is a block diagram of an electronic system including a semiconductor device according to the inventive concept;

FIG. 19 is a block diagram of a memory card including a semiconductor device according to the inventive concept; and

FIG. 20 is a perspective view of a smart phone including a semiconductor device according to the inventive concept.

### DETAILED DESCRIPTION OF EXAMPLE EMBODIMENTS

Reference will now be made in detail to representative embodiments, examples of which are illustrated in the accompanying drawings to help understanding the structure and effects of the inventive concept. However, representative embodiments are not limited to the embodiments illustrated hereinafter, and the representative embodiments herein are rather introduced to provide easy and complete understanding of the scope and spirit of representative embodiments. In the drawings, the sizes of constituting elements are exaggerated for clarity, and ratios of the respective constituting elements may be exaggerated, that is, greater or less than their actual values.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,”, “directly connected to”, or “directly coupled to” another element or layer, there are no intervening elements or layers present. Other expressions, such as, “between” and “directly between”, describing the relationship between the constituent elements, may be construed in the same manner.

The terms such as “first” and “second” are used herein merely to describe a variety of constituent elements, but the constituent elements are not limited by the terms. The terms are used only for the purpose of distinguishing one constituent element from another constituent element. For example, without departing from the right scope of the inventive concept, a first constituent element may be referred to as a second constituent element, and vice versa.

The expression of singularity in the present specification includes the expression of plurality unless clearly specified otherwise in context. Also, the terms such as “include” or “comprise” may be construed to denote a certain characteristic, number, step, operation, constituent element, or a combination thereof, but may not be construed to exclude the existence of or a possibility of addition of one or more other characteristics, numbers, steps, operations, constituent elements, or combinations thereof.

Unless defined otherwise, all terms used herein including technical or scientific terms have the same meanings as those generally understood by those skilled in the art to which the inventive concept may pertain. For example, the term “group IV compound semiconductor” will be understood as referring to a compound having semiconductor elements found in Group IV of the Periodic Table, e.g., SiGe. As used herein, the term “and/or” includes any and all combinations of one or more of the associated listed items. Expressions such as “at least one of,” when preceding a list of elements, modify the entire list of elements and do not modify the individual elements of the list.

Representative embodiments of a semiconductor device according to the inventive concept, as exemplified by a complementary metal-oxide-semiconductor (CMOS) device 10, will now be described in detail.

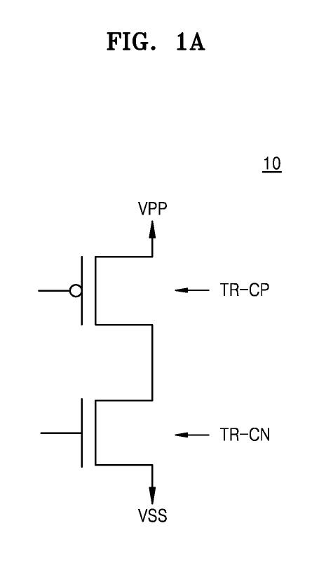

Referring first to FIG. 1A, the CMOS device 10 includes a P-type metal-oxide-semiconductor field effect transistor (PMOSFET) TR-CP and an N-type metal-oxide-semiconductor field effect transistor (NMOSFET) TR-CN. A source of the PMOSFET TR-CP and a drain of the NMOSFET TR-CN are connected to each other, and a power supply voltage VPP may be applied to a drain of the PMOSFET TR-CP, and a ground voltage VSS may be applied to a source of the NMOSFET TR-CN.

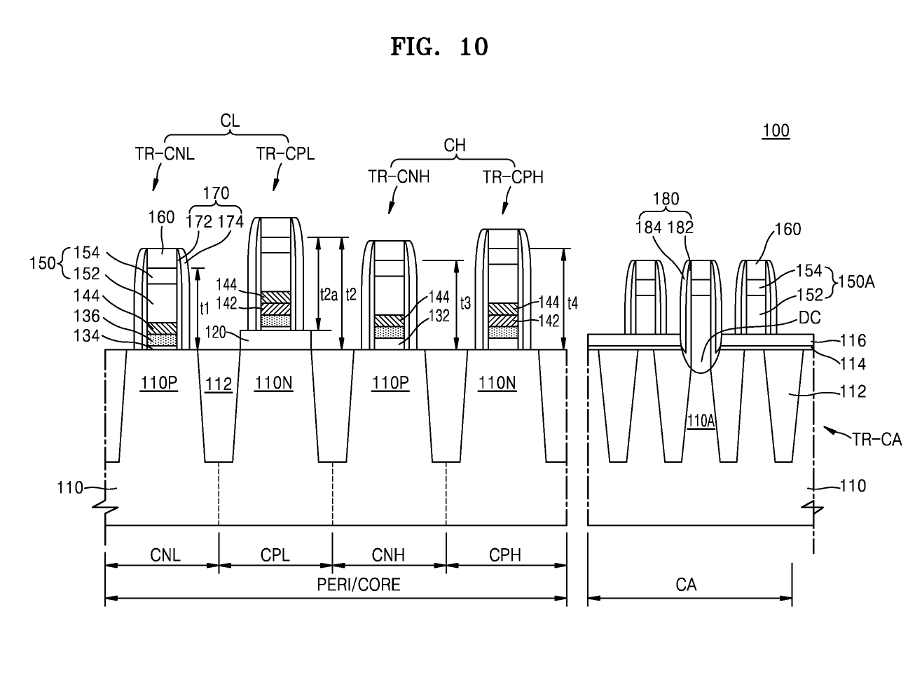

The CMOS device 10 may function as an inverter. The CMOS device 10 may correspond to a low voltage CMOS device (CL of FIGS. 10 through 13) or a high voltage CMOS device (CH of FIGS. 10 through 13), disposed in a peripheral/core region (PERI/CORE of FIGS. 10 through 13) of a semiconductor device (100, 100a, 102, and 102a of FIGS. 10 through 13).

Referring to FIG. 1B, the NMOSFET TR-CN is formed in an active region ACT-P of P-type conductivity, e.g., a P-WELL, and the PMOSFET TR-CP is formed in an active region ACT-N of N-type conductivity, e.g., an N-WELL. The first and second active regions ACT-P and ACT-N are defined by a device isolation layer ST1. The CMOS device 10 further includes gates. The gates may be constituted by a gate line GL extending across the first active region ACT-P and the second active region ACT-N. A first gate insulating layer (not shown) is interposed between the gate line GL and the first active region ACT-P. A second gate insulating layer (not shown) is interposed between the gate line GL and the second active region ACT-N. That is, in this example, the NMOSFET TR-CN in the first active region ACT-P is constituted by the gate line GL and the first gate insulating layer, and the PMOSFET TR-CP in the second active region ACT-N is constituted by the gate line GL and the second gate insulating layer.

The first active region ACT-P and the second active region ACT-N may be electrically connected to each other through a first bit line BL and contact plugs CNT disposed to one side of the gate line GL and to which the first bit line BL is electrically connected. The ground voltage VSS and the power supply voltage VPP may be applied to the first active region ACT-P and the second active region ACT-N, respectively, through second bit lines BL and contact plugs CNT disposed on the other side of the gate line GL and to which the second bit lines BL are respectively connected.

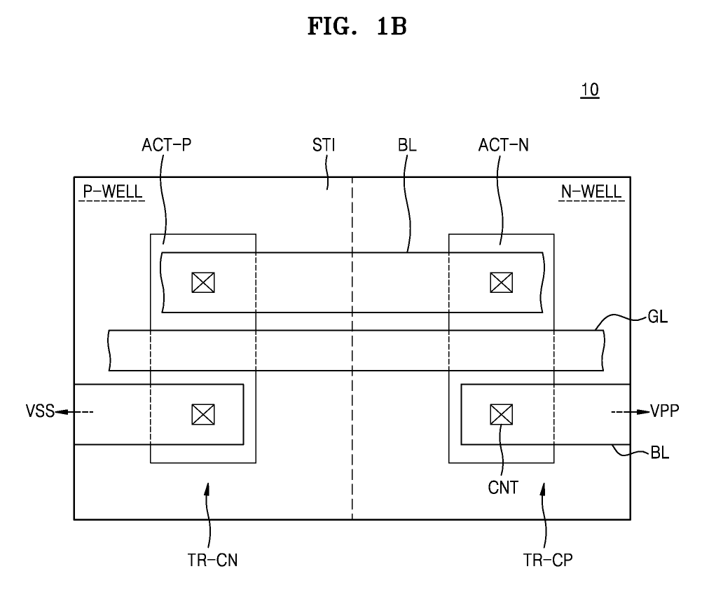

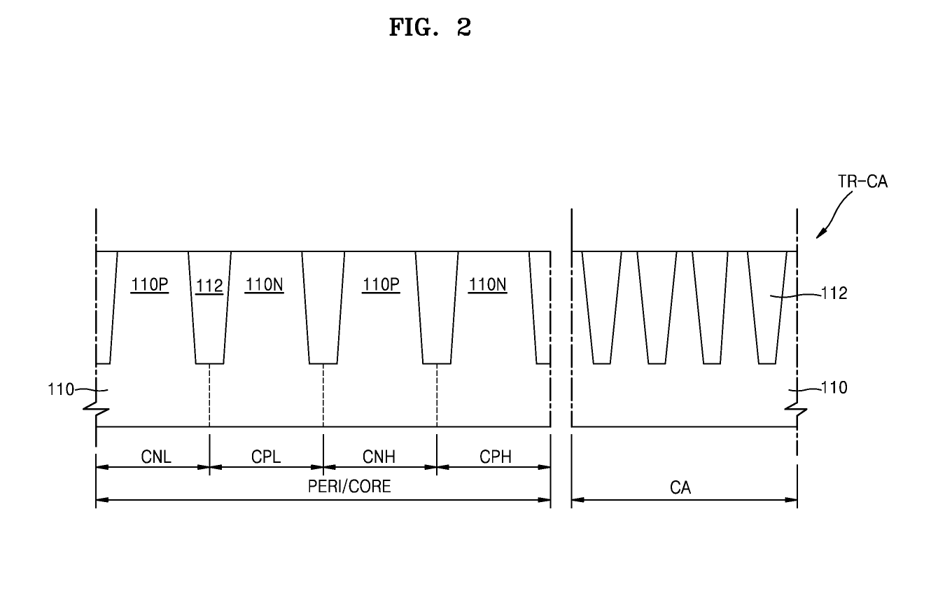

A representative embodiment of a method of manufacturing a semiconductor device of the type described above, according to the inventive concept, will now be described with reference to FIGS. 2 through 9.

Referring first to FIG. 2, a device isolation layer 112 may be formed in a semiconductor substrate 110. The semiconductor substrate 110 has a cell array region CA and a peripheral/core region PERI/CORE disposed around the cell array region CA. An array of memory cells may be formed at the cell array region CA. Semiconductor devices forming circuits that control the memory cells may be formed at the peripheral/core region PERI/CORE.

The semiconductor substrate 100 may comprise crystalline, polycrystalline, or amorphous silicon (Si). The semiconductor substrate 100 may comprise germanium (Ge). The semiconductor substrate 100 may comprise a semiconductor compound, such as silicon germanium (SiGe), silicon carbide (SiC), gallium arsenide (GaAs), indium arsenide (InAs), or indium phosphide (InP). The semiconductor substrate may be a bulk substrate or the semiconductor substrate 100 may be a silicon-on-insulator (SOI) substrate or may include a buried oxide (BOX) layer. In this example, the semiconductor substrate 100 includes wells (doped regions) containing impurities. Alternatively, the semiconductor substrate 100 may include a layer or structure containing (doped to include) impurities.

The device isolation layer 112 may be a single layer of an oxide, a nitride, or silicon oxynitride, or may be a composite of a combination of two or more of such materials. Active regions 110P, 110N, and 110A may be defined in the semiconductor substrate 110 by the device isolation layer 112.

The peripheral/core region PERI/CORE may have first through fourth transistor regions CNL, CPL, CNH, and CPH separated from one another by the device isolation layer 112. Although FIG. 2 shows the first through fourth transistor regions CNL, CPL, CNH, and CPH disposed in a line, this case is only an example.

The first and third transistor regions CNL and CNH of the semiconductor substrate 110 of may correspond to the P-WELL shown in FIG. 1B, and a first active region 110P defined by the device isolation layer 112 in the first and third transistor regions CNL and CNH of the semiconductor substrate 110 may correspond to the active region ACT-P shown in FIG. 1B. The second and fourth transistor regions CPL and CPH of the semiconductor substrate 110 may correspond to the N-WELL shown in FIG. 1B, and a second active region 110N defined by the device isolation layer 112 in the second and fourth transistor regions CPL and CPH of the semiconductor substrate 110 may correspond to the active region ACT-N shown in FIG. 1B. In this example, therefore, the first active region 110P has a P-type conductivity, and the second active region 110N has an N-type conductivity.

A cell transistor TR-CA is formed in the cell array region CA. As will be described later in more detail, the cell transistor TR-CA includes a buried gate electrode in the semiconductor substrate 110 and a cell gate insulating layer interposed between the semiconductor substrate 110 and the buried gated electrode

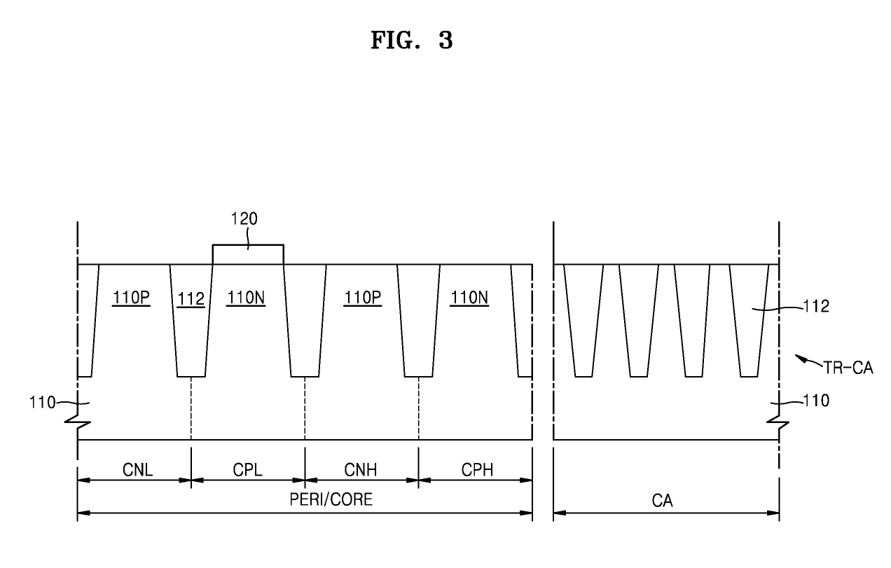

Referring to FIG. 3, a group IV compound semiconductor layer 120 is formed on the second active region 110N of the second transistor region CPL. The group IV compound semiconductor layer 120 may be formed of, for example, Si—Ge. The group IV compound semiconductor layer 120 may be formed to have a thickness of about 20 Å to about 200 Å. When the group IV compound semiconductor layer 120 is formed of Si—Ge, the concentration of the Ge may be about 10 atom % to about 50 atom %. The group IV compound semiconductor layer 120 may be formed by a selective epitaxial growth (SEG) process which includes forming a mask (not shown) exposing the second transistor region CPL while covering the rest of the semiconductor substrate 110, and then growing the group IV compound semiconductor on the exposed second transistor region CPL of the substrate 110. The mask may include a hard mask pattern and a photoresist pattern stacked in the hard mask pattern. The hard mask pattern may be formed of, for example, silicon oxide, silicon nitride, or silicon oxynitride. As a result of the SEG process, the group IV compound semiconductor layer 120 is formed on the second active region 110N in the second transistor region CPL and may but not on the device isolation layer 112.

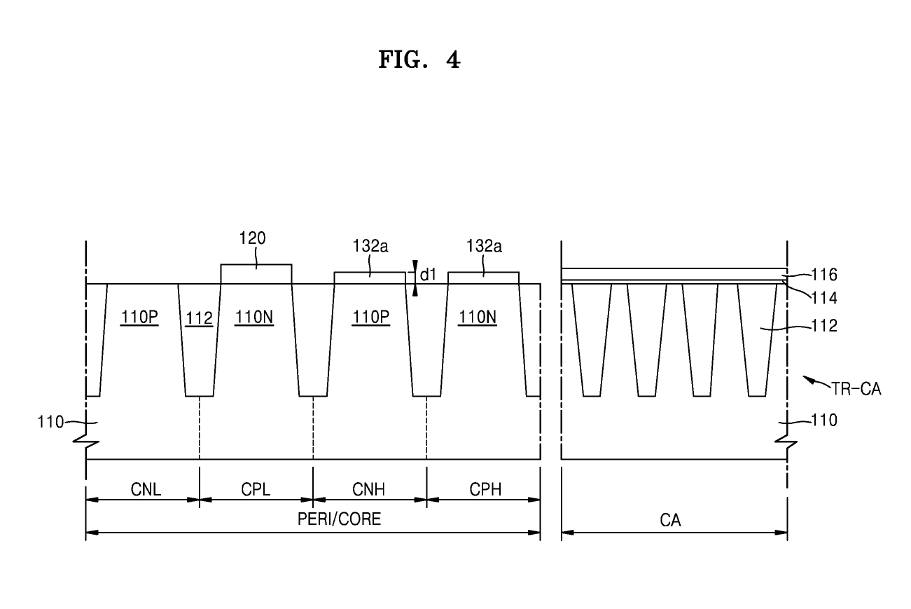

Referring to FIG. 4, a first insulating layer 114 and a second insulating layer 116 are formed on the semiconductor substrate 110 in the cell array region CA. For example, the first insulating layer 114 and the second insulating layer 116 are sequentially formed each over the entire surface of the semiconductor substrate 110, and then the first and second insulating layers 114 and 116 are removed from the peripheral/core region PERI/CORE such that the first and second active regions 110P and 110N are again exposed. The first insulating layer 114 may be formed of an oxide, and the second insulating layer 116 may be formed of a nitride. However, the inventive concept is not limited thereto.

In the peripheral/core region PERI/CORE, first dielectric layer 132a is formed on the first active region 110P of the third transistor region CNH and the second active region 110N of the fourth transistor region CPH. The first dielectric layer 132a may be formed of, for example, silicon oxide, silicon nitride, silicon oxynitride, or oxide/nitride/oxide (ONO). The first dielectric layer 132a may be formed to have a first thickness d1 of about 20 Å to about 50 Å. The first dielectric layer 132a may be formed to be thinner than the group IV compound semiconductor layer 120.

The first dielectric layer 132a may be formed by chemical vapor deposition (CVD) or atomic layer deposition (ALD). The first dielectric layer 132a may be formed by forming a first dielectric material layer over the entire surface of the semiconductor substrate 110 and then removing the first dielectric layer 132a from the first and second transistor regions CNL and CPL using a mask (not shown) and a wet etching process. In this process, a second dielectric material layer may be formed in the cell array region CA. However, the second dielectric material layer may be removed when removing the portion of the first dielectric layer 132a from the first and second transistor regions CNL and CPL.

In the present specification, processes may be described as being performed separately with respect to the cell array region CA and the peripheral/core region PERI/CORE. For example, when describing a manufacturing process performed in the peripheral/core region PERI/CORE, a detailed description and illustration may be omitted if one of the cell array region CA and the peripheral/core region PERI/CORE is covered by a mask pattern during the manufacturing process or a part formed in one of the cell array region CA and the peripheral/core region PERI/CORE during the manufacturing process is removed after the manufacturing process is performed for other part, and thus, there is no change in a resultant structure.

That is, in the case that the first dielectric material layer for forming the first dielectric layer 132a is removed in the cell array region CA after the first dielectric material layer is formed in both the cell array region CA and the peripheral/core region PERI/CORE, as described above with reference to FIG. 4, description and illustration for the cell array region CA may be omitted. Likewise, in the case that the first and second insulating layers 114 and 116 are removed in the peripheral/core region ray region PERI/CORE after the first and second insulating layers 114 and 116 are formed in both the cell array region CA and the peripheral/core region PERI/CORE, description and illustration for the peripheral/core region ray region PERI/CORE may be omitted. In addition, in the case that in subsequent processes as well as in any one process, the first dielectric material layer or the first and second insulating layers 114 and 116 are removed in the cell array region CA or the peripheral/core region PERI/CORE, description and illustration for a corresponding region may be omitted.

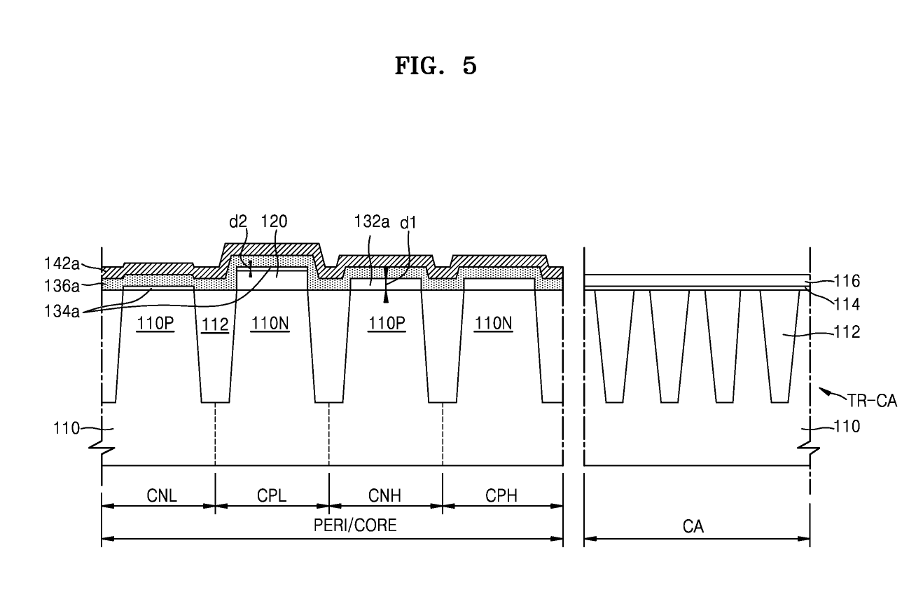

Referring to FIG. 5, in the peripheral/core region PERI/CORE, second dielectric layer 134a is formed on the first active region 110P of the first transistor region CNL and the second active region 110N of the second transistor region CPL. The second dielectric layer 134a may be formed of, for example, silicon oxide, silicon nitride, silicon oxynitride, or ONO. The second dielectric layer 134a may have a thickness d2 of about 5 Å to about 15 Å. The thickness d2, that is, the thickness of the second dielectric layer 134a, may be less than the thickness d1 of the first dielectric layer 132a. The second dielectric layer 134a may be formed, for example, by thermal oxidation. When the second dielectric layer 134a is formed by thermal oxidation, the second dielectric layer 134a may be formed only on the first active region 110P of the first transistor region CNL and the group IV compound semiconductor layer 120 of the second transistor region CPL which are exposed portions of the semiconductor substrate 110.

Next, high-k insulating layer 136a and first metal gate material layer 142a are sequentially formed to cover the entire surface of the peripheral/core region PERI/CORE of the semiconductor substrate 110. The high-k insulating layer 136a and the first metal gate material layer 142a may be formed conformally on the semiconductor substrate 110. Also, the high-k insulating layer 136a may be a high-k dielectric film formed of a dielectric material having a dielectric constant greater than that of silicon oxide.

For example, the high-k insulating layer 136a may have a dielectric constant of about 10 to about 25. The high-k insulating layer 136a may be formed of at least one selected material selected from the group consisting of hafnium oxide (HfO), hafnium silicate (HfSiO), hafnium oxynitride (HfON), hafnium silicon oxynitride (HfSiON), lanthanum oxide (LaO), lanthanum oxide nitride (LaON), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), aluminum oxide nitride (AlON), and lead scandium tantalum oxide (PbScTaO). For example, the high-k insulating layer 136a may be formed of HfO₂, Al₂O₃, HfAlO₃, Ta₂O₃, or TiO₂.

The first metal gate material layer 142a may be formed of a single layer or multiple layers. For example, the first metal gate material layer 142a may be formed of TiN, TiN/TaN, Al₂O₃/TiN, Al/TiN, TiN/Al/TiN, TiN/TiON, Ta/TiN, or TaN/TiN, and TiN may be replaced with TaN, TaCN, TiCN, CoN, or CoCN. The first metal gate material layer 142a may be formed to a thickness of about 30 Å to about 60 Å.

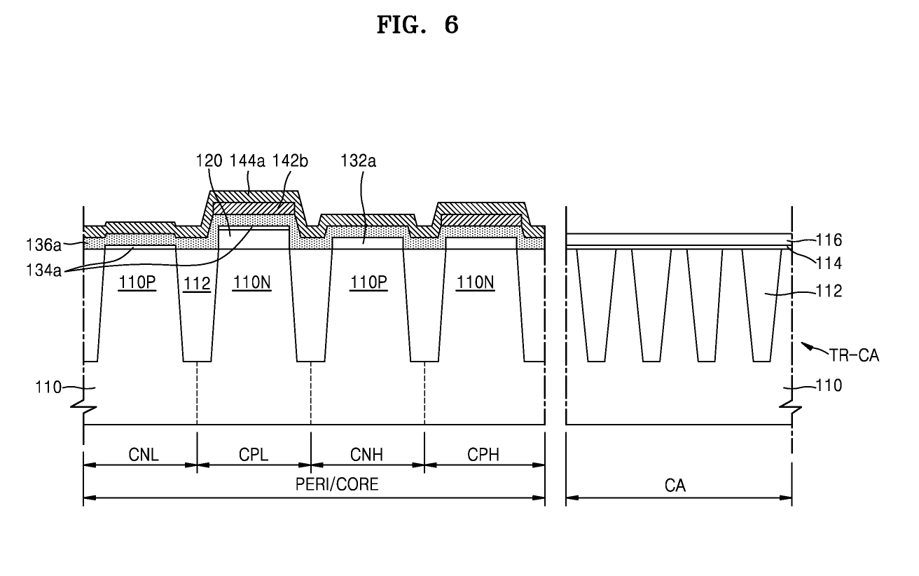

Referring to FIG. 6, next, a first metal gate material pattern 142b is formed by removing the first metal gate material layer 142a from the first and third transistor regions CNL and CNH. The first metal gate material layer 142a may also be removed from the device isolation layer 112 to form the first metal gate material pattern 142b. As a result, the first metal gate material pattern 142b is disposed on the second active region 110N of the second and fourth transistor regions CPL and CPH.

A second metal gate material layer 144a is formed to cover the peripheral/core region PERI/CORE in which the first metal gate material pattern 142b is formed. The second metal gate material layer 144a may be formed of a single layer of material or a composite of materials. For example, the second metal gate material layer 144a may be formed of La/TiN, Mg/TiN, Sr/TiN, LaO/TiN or LaON/TiN. The second metal gate material layer 144a may be formed to a thickness of about 30 Å to about 60 Å. The second metal gate material layer 144a may be formed to conformally cover the semiconductor substrate 110.

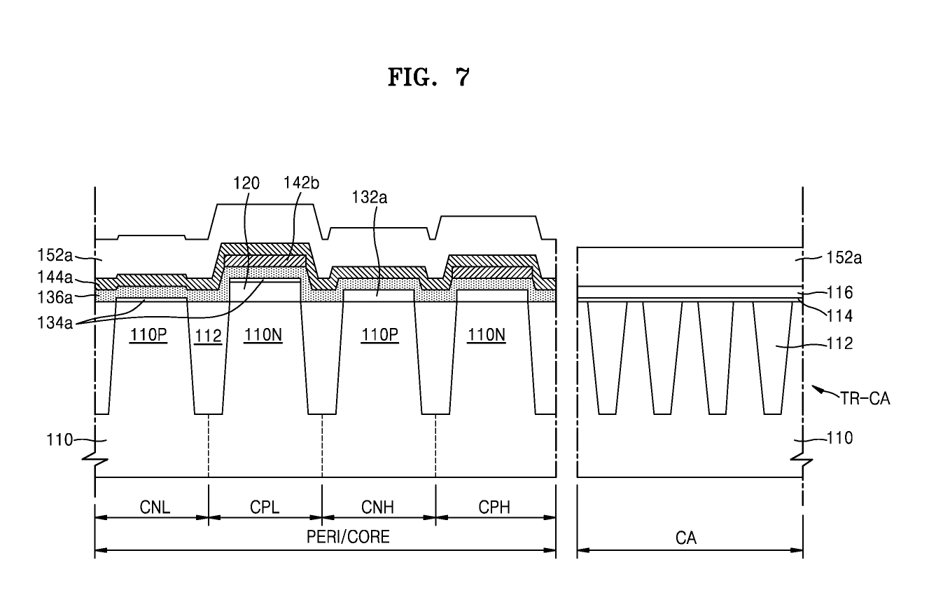

Referring to FIG. 7, first conductive material layer 152a is then formed to cover the semiconductor substrate 110. The first conductive material layer 152a may be formed in both the cell array region CA and the peripheral/core region PERI/CORE.

The first conductive material layer 152a may be formed of a single layer or a composite. The first conductive material layer 152a may be formed of, for example, doped polysilicon or metal such as W, Mo, Au, Cu, Al, Ni, or Co.

The first conductive material layer 152a may be formed to a thickness of 500 Å to 1000 Å, for example. The first conductive material layer 152a may be formed to conformally cover the semiconductor substrate 110.

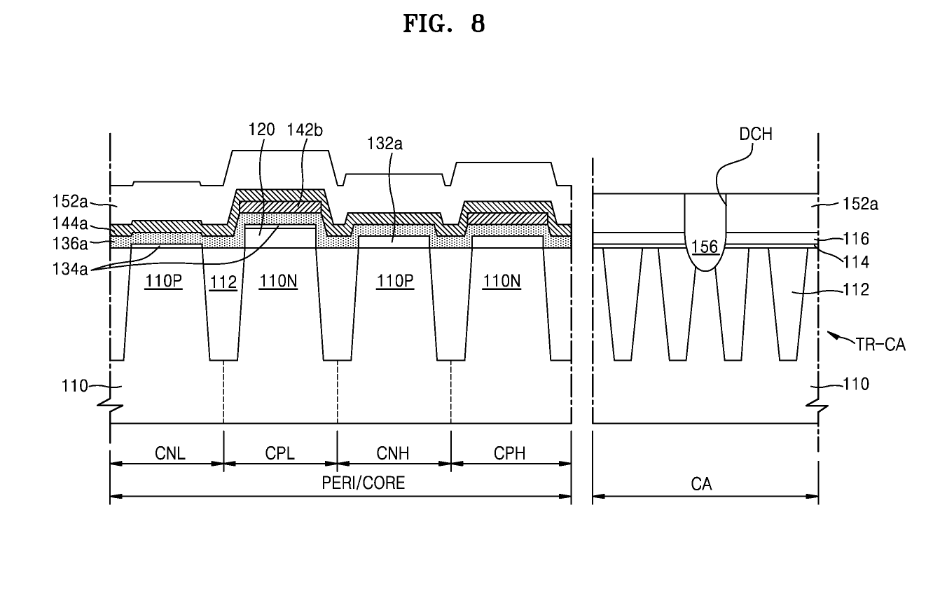

Referring to FIG. 8, a direct contact hole DCH is formed through the first insulating layer 114, the second insulating layer 116, and the first conductive material layer 152a in the cell array region CA to expose the semiconductor substrate 110. Next, a contact plug 156 is formed to fill the direct contact hole DCH and contact the semiconductor substrate 110. A silicide layer (not shown) may be formed so as to be interposed between the semiconductor substrate 110 and the contact plug 156. The silicide layer may be formed of, for example, WSiₓ, NiSiₓ, CoSiₓ, NiPtSiₓ, or NiPtSiC. The contact plug 156 may be formed of a material that is similar to that of the first conductive material layer 152a.

The contact plug 156 may be formed by forming a plug material (not shown) to fill the direct contact hole DCH and cover the semiconductor substrate 110, and then performing a chemical mechanical polishing or etch-back process to remove all of the plug material except for that occupying the direct contact hole DCH.

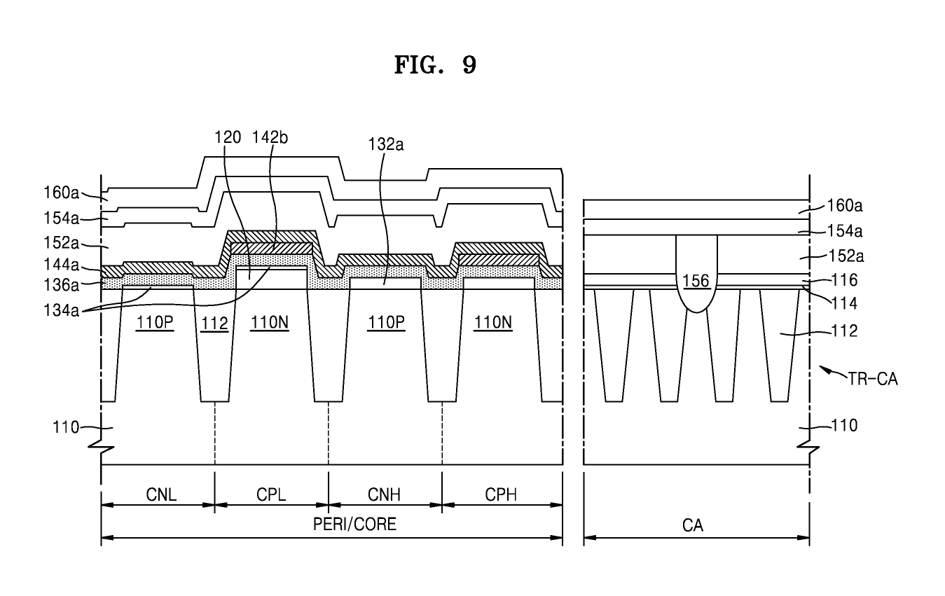

Referring to FIG. 9, second conductive material layer 154a and capping material layer 160a are sequentially formed to cover the semiconductor substrate 110. The second conductive material layer 154a and the capping material layer 160a may be formed in both the cell array region CA and the peripheral/core PERI/CORE.

The second conductive material layer 154a may be formed of, for example, doped polysilicon or metal such as W, Mo, Au, Cu, Al, Ni, or Co.

The first and second conductive material layers 152a and 154a together form a composite, such as a doped polysilicon/silicide layer, ohmic layer/barrier layer/metal layer, doped polysilicon/ohmic layer/barrier layer/metal layer, or doped polysilicon/ohmic layer/barrier layer/ohmic layer/metal layer. In the case of a doped polysilicon/silicide layer, the silicide layer may be WSiₓ, NiSiₓ, CoSiₓ, NiPtSiₓ, or NiPtSiC. Examples of the ohmic layer are WSix, WN, TiSiN, and TiSix. Examples of the barrier layer are TiN, TaN, and CoN. Examples of the metal layer are W, Mo, Au, Cu, Al, Ni, and Co.

The capping material layer 160a may be formed of silicon nitride. Although FIG. 9 shows the thickness of the capping material layer 160a as less than the sum of the thickness of the first conductive material layer 152a and the thickness of the second conductive material layer 154a, the inventive concept is not limited thereto. That is, the capping material layer 160a may be formed to a thickness that is greater than the sum of the thickness of the first conductive material layer 152a and the thickness of the second conductive material layer 154a.

Referring to both FIG. 9 and FIG. 10, in the peripheral/core region PERI/CORE, the first dielectric layer 132a, the second dielectric layer 134a, the high-k insulating layer 136a, the first metal gate material pattern 142b, the second metal gate material layer 144a, the first conductive material layer 152a, the second conductive material layer 154a, and the capping material layer 160a are patterned.

Specifically, in the first transistor region CNL, a first stack structure, in which a second dielectric layer 134, a high-k insulating layer 136, a second metal gate layer 144, first and second conductive material layers 152 and 154, and a capping material layer 160 are stacked, is formed by partially removing the second dielectric layer 134a, the high-k insulating layer 136a, the second metal gate material layer 144a, the first conductive material layer 152a, the second conductive material layer 154a, and the capping material layer 160a. In the second transistor region CPL, a second stack structure, in which a second dielectric layer 134, a high-k insulating layer 136, first and second metal gate layers 142 and 144, first and second conductive material layers 152 and 154, and a capping material layer 160 are stacked, is formed by partially removing the second dielectric layer 134a, the high-k insulating layer 136a, the first metal gate material pattern 132a, the second metal gate material layer 144a, the first conductive material layer 152a, the second conductive material layer 154a, and the capping material layer 160a. In the third transistor region CNH, a third stack structure, in which a first dielectric layer 132, a high-k insulating layer 136, a second metal gate layer 144, first and second conductive material layers 152 and 154, and a capping material layer 160 are stacked, is formed by partially removing the first dielectric layer 132a, the high-k insulating layer 136a, the second metal gate material layer 144a, the first conductive material layer 152a, the second conductive material layer 154a, and the capping material layer 160a. In the fourth transistor region CPH, a fourth stack structure, in which a first dielectric layer 132, a high-k insulating layer 136, first and second metal gate layers 142 and 144, first and second conductive material layers 152 and 154, and a capping material layer 160 are stacked, is formed by partially removing the first dielectric layer 132a, the high-k insulating layer 136a, the first metal gate material pattern 132a, the second metal gate material layer 144a, the first conductive material layer 152a, the second conductive material layer 154a, and the capping material layer 160a.

The first conductive material layer 152 and the second conductive material layer 154 may together form a gate electrode 150.

In this embodiment, the first stack structure does not cover a portion of the first active region 110P in the first transistor region CNL. In the second transistor region CPL, the second stack structure does not cover a portion of the group IV compound semiconductor layer 120. In the third transistor region CNH, the third stack structure does not cover a portion of the first active region 110P. In the fourth transistor region CPH, the fourth stack structure does not cover a portion of the second active region 110N.

In the first transistor region CNL, the first stack structure may include a first gate insulating layer structure, which includes the second dielectric layer 134 and the high-k insulating layer 136, and a first gate electrode structure which includes the second metal gate layer 144 and the first and second conductive material layers 152 and 154.

In the second transistor region CPL, the second stack structure may include a second gate insulating layer structure, which includes the second dielectric layer 134 and the high-k insulating layer 136, and a second gate electrode structure which includes the first and second metal gate layers 142 and 144 and the first and second conductive material layers 152 and 154.

In the third transistor region CNH, the third stack structure may include a third gate insulating layer structure, which includes the first dielectric layer 132 and the high-k insulating layer 136, and a third gate electrode structure which includes the second metal gate layer 144 and the first and second conductive material layers 152 and 154.

In the fourth transistor region CPH, the fourth stack structure may include a fourth gate insulating layer structure, which includes the first dielectric layer 132 and the high-k insulating layer 136, and a fourth gate electrode structure which includes the first and second metal gate layers 142 and 144 and the first and second conductive material layers 152 and 154.

The thicknesses of the first dielectric layers 132 of the third and fourth gate insulating layer structures are greater than those of the second dielectric layers 134 of the first and second gate insulating layer structures, and the high-k insulating layers 136 in the first through fourth transistor regions CNL, CPL, CNH, and CPH are substantially the same in depth. Accordingly, the thicknesses of the third and fourth gate insulating layer structures may be greater than those of the second and fourth first and second gate insulating layer structured.

Next, in the first through fourth transistor regions CNL, CPL, CNH, and CPH, a gate spacer 170 including a first spacer layer 172 and a second spacer layer 174 may be formed to cover the sides of the first through fourth stack structures.

Through processes described above, first through fourth MOSFETs TR-CNL, TR-CPL, TR-CNH, and TR-CPH are formed in the first through fourth transistor regions CNL, CPL, CNH, and CPH, respectively.

In the first transistor region CNL, the second dielectric layer 134 may contact the first active region 110P of the semiconductor substrate 110. In the second transistor region CPL, the second dielectric layer 134 may contact the group IV compound semiconductor layer 120. In the third transistor region CNH, the first dielectric layer 132 may contact the first active region 110P of the semiconductor substrate 110. In the fourth transistor region CPH, the first dielectric layer 132 may contact the second active region 110N of the semiconductor substrate 110.

The first and third MOSFETs TR-CNL and TR-CNH are NMOSFETs. The second and fourth MOSFETs TR-CPL and TR-CPH are PMOSFETs. The absolute value of an operating voltage of the first MOSFET TR-CNL may be lower than that of an operating voltage of the third MOSFET TR-CNH. The absolute value of an operating voltage of the second MOSFET TR-CPL may be lower than that of an operating voltage of the fourth MOSFET TR-CPH. The first and second MOSFETs TR-CNL and TR-CPL may form a low voltage CMOS device CL together. The third and fourth MOSFETs TR-CNH and TR-CPH may form a high voltage CMOS device CH.

The terms high voltage and low voltage used above obviously refer to voltages relative to one another. As examples, the absolute value of an operating voltage of the third and fourth MOSFETs TR-CNH and TR-CPH of the high voltage CMOS device may be about 2.5V to about 5V, whereas the absolute value of an operating voltage of the first and second MOSFETs TR-CNL and TR-CPL of the low voltage CMOS device CL may be about 0.5V to about 2V.

The gate electrode structures of the first through fourth MOSFETs TR-CNL, TR-CPL, TR-CNH, and TR-CPH have respective heights t1, t2, t3, and t4 relative to the main surface of the semiconductor substrate 110. The height t2 may be greater than the height t4, the height t4 may be greater than the height t3, and the height t3 may be greater than the height t1. The second gate electrode structure of the second MOSFET TR-CPL may have a height t2a with respect to the upper surface of the group IV compound semiconductor layer 120, and the height t2a may be less than the height t4.

The semiconductor device 100 may be, for example, a dynamic random access memory (DRAM) semiconductor device. In this case, DRAM memory cells are disposed in an array in the cell array region CA of the semiconductor device 100. An inverter chain, an input/output (I/O) circuit, and the like may be formed in a peripheral circuit region of the peripheral/core region PERI/CORE, and a sense amplifier circuit, a sub-word line driver circuit, and the like may be formed in a core region of the peripheral/core region PERI/CORE.

In the case of a PMOSFET, a group IV compound semiconductor layer, such as Si—Ge having hole mobility that is greater than that of Si, may be used as a channel to improve transistor performance. However, in such a PMOSFET in which the absolute value of its operating voltage is relatively high, there is the potential for a relatively great amount of gate induced drain leakage (GIDL) when the PMOSFET is in a stand-by state.

In the semiconductor device 100 according to the representative embodiment, the second MOSFET TR-CPL in which the absolute value of an operating voltage is relatively low uses the group IV compound semiconductor layer 120 as a channel, and the fourth MOSFET TR-CPH in which the absolute value of an operating voltage is relatively high uses the second active region 110N of the semiconductor substrate 110 as a channel. Accordingly, leakage current is relatively low in a stand-by state, i.e., the transistors exhibit improved performance compared to the case described in the preceding paragraph.

In examples of this embodiment, the low voltage CMOS device CL including the first MOSFET TR-CNL and the second MOSFET TR-CPL constitute an inverter chain circuit and/or a sense amplifier circuit. On the other hand, the high voltage CMOS device CH including the third MOSFET TR-CNH and the fourth MOSFET TR-CPH constitute a sub-word line driver circuit and/or a row decoder circuit.

In the cell array region CA, a cell stack structure in which a first conductive material layer 152, a second conductive material layer 154 and a capping material layer 160 are stacked is formed by patterning the first conductive material layer 152a, the second conductive material layer 154a, and the capping material layer 160a. In the cell array region CA, the first and second conductive material layers 152 and 154 may form a bit line electrode 150A. A portion of the contact plug 156 may also be removed in the process of forming the cell stack structure and thus, a direct contact plug DC that electrically connects the bit line electrode 150A to a cell active region 110A may be formed. The bit line electrode 150A formed in the cell array region CA may be electrically connected to a drain region of a cell transistor TR-CA. The bit line electrode 150A may be formed of the same material as the gate electrode 150, and together with the gate electrode 150.

Next, a bit line spacer 180 including a first cell spacer layer 182 and a second cell spacer layer 184 may be formed to cover the side of the cell stack structure.

A gate spacer 170 and the bit line spacer 180 may be formed by discrete processes. However, the gate spacer 170 and the bit line spacer 180 may be simultaneously formed of the same material through the same process.

The gate spacer 170 and the bit line spacer 180 may be formed of, for example, silicon oxide, silicon nitride, or a combination thereof and in the latter case may include an internal layer of air confined between two layers. In the current embodiment, although the gate spacer 170 and the bit line spacer 180 each are formed of two layers, the inventive concept is not limited thereto. For example, the gate spacer 170 and the bit line spacer 180 each may be formed of a single layer or three layers.

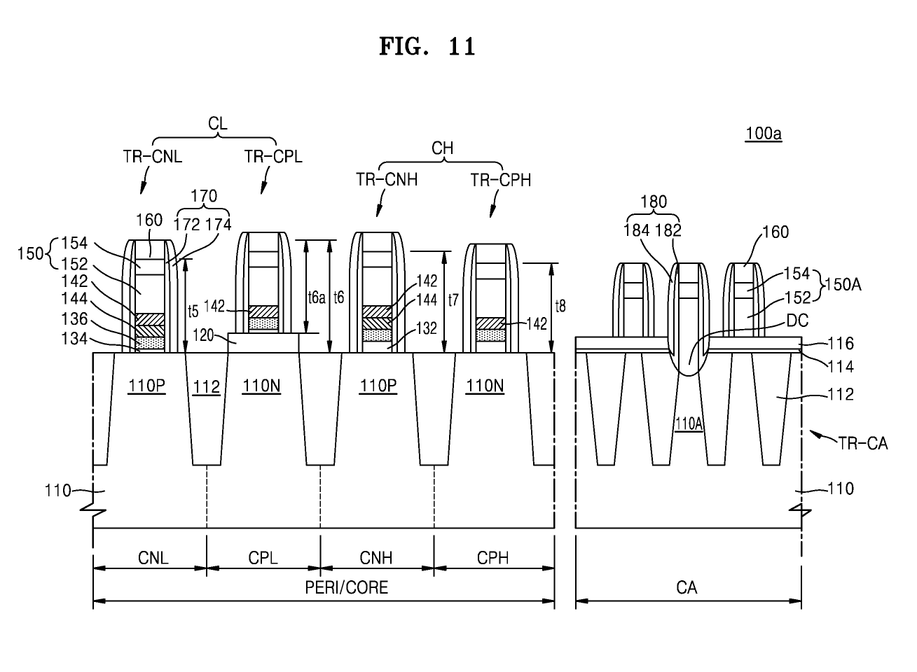

FIG. 11 is a cross-sectional view of another representative embodiment of a semiconductor device 100a according to of the inventive concept. The semiconductor device 100a is similar to the semiconductor device 100 shown in FIG. 10 except with respect to the first and second metal gate layers 142 and 144 of the first through fourth MOSFETs TR-CNL, TR-CPL, TR-CNH, and TR-CPH.

In this embodiment, the gate electrode structure of the first MOSFET TR-CNL and the gate electrode structure of the third MOSFET TR-CNH each include a second metal gate layer 144 and a first metal gate layer 142 stacked on the second metal gate layer 144. The gate electrode structure of the second MOSFET TR-CPL and the gate electrode structure of the fourth MOSFET TR-CPH each include a first metal gate layer 142 but not the second metal gate layer 144.

That is, in the semiconductor device 100 shown in FIG. 10, the first metal gate layer 142 is first formed in the second and fourth transistor regions CPL and CPH and then the second metal gate layer 144 is formed in the first through fourth transistor regions CNL, CPL, CNH, and CPH, whereas in the semiconductor device 100a shown in FIG. 11, the second metal gate layer 144 is first formed in the first and third transistor regions CNL and CNH and then the first metal gate layer 142 is formed in the first through fourth transistor regions CNL, CPL, CNH, and CPH.

On the other hand, in both the semiconductor device 100 shown in FIG. 10 and the semiconductor device 100a the high-k insulating layer 136 of the first MOSFET TR-CNL contacts the second metal gate layer 144, the high-k insulating layer 136 of the second MOSFET TR-CPL contacts the first metal gate layer 142, the high-k insulating layer 136 of the third MOSFET TR-CNH contacts the second metal gate layer 144, and the high-k insulating layer 136 of the fourth MOSFET TR-CPH contacts the first metal gate layer 142.

The gate electrode structures of the first through fourth MOSFETs TR-CNL, TR-CPL, TR-CNH, and TR-CPH have respective heights t5, t6, t7, and t8 relative to the main surface of the semiconductor substrate 110. The height t6 may be greater than the height t7, and the third height t7 may be greater than the height t5 and the height t8. The gate electrode structure of the second MOSFET TR-CPL may have a height t6a with respect to the upper surface of a group IV compound semiconductor layer 120, and the height t6a may be less than the height t5 and the height t8.

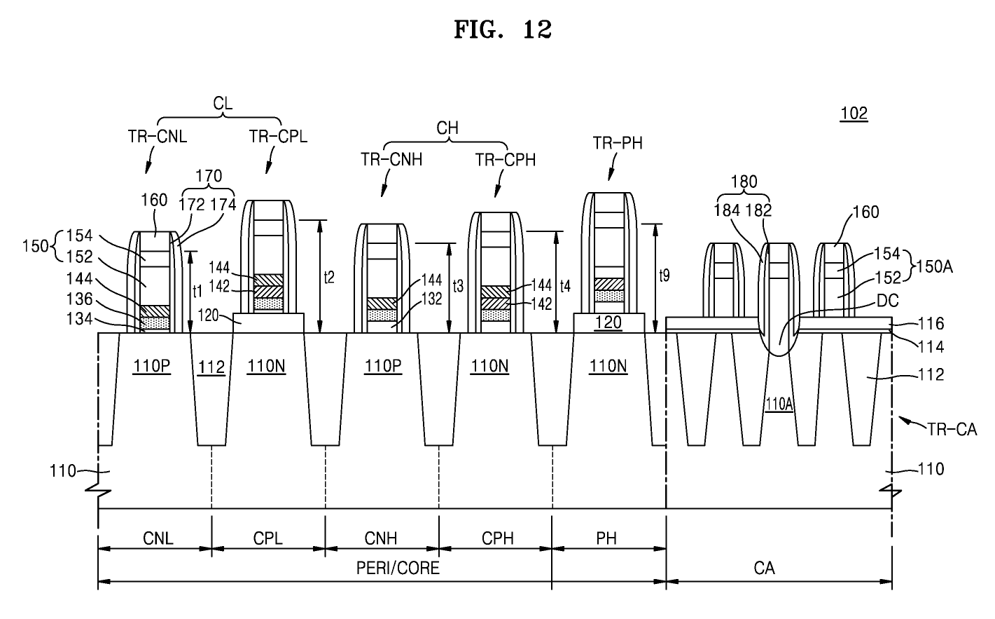

FIG. 12 is a cross-sectional view of another representative embodiment of a semiconductor device 102 according to the inventive concept. Regarding the detailed description of FIG. 12, details overlapping with details described with reference to FIG. 10 are omitted.

Referring to FIG. 12, the semiconductor device 102 further includes a fifth transistor region PH formed in a peripheral/core region PERI/CORE. That is, the semiconductor device 102 shown in FIG. 12 is similar to the semiconductor device 100 shown in FIG. 10 except that the semiconductor device 102 further includes a fifth MOSFET TR-PH formed in the fifth transistor region PH.

First and second MOSFETs TR-CNL and TR-CPL may form a low voltage CMOS device CL together, third and fourth MOSFETs TR-CNH and TR-CPH may form a high voltage CMOS device CH, and the fifth MOSFET TR-PH may operate as a switch device.

The fifth MOSFET TR-PH may be a PMOSFET. The fifth MOSFET TR-PH has substantially the same structure as the fourth MOSFET TR-CPH of the high voltage CMOS device CH. However, the fourth MOSFET TR-CPH uses a second active region 110N of a semiconductor substrate 110 as a channel, whereas the fifth MOSFET TR-PH uses a group IV compound semiconductor layer 120 as a channel. That is, the semiconductor device 102 may be formed by a manufacturing method that is substantially the same as the method of manufacturing the semiconductor device 100 shown in FIG. 10, except that the group IV compound semiconductor layer 120 is formed also in the fifth transistor region PH, which is a high voltage transistor region, when the group IV compound semiconductor layer 120 is formed in the second transistor region CPL and a stack structure that is the same as the fourth stack structure of the fourth MOSFET TR-CHP is formed on the group IV compound semiconductor layer 120 formed in the fifth transistor region PH.

The fifth MOSFET TR-PH may be designed so that the absolute value of the threshold voltage of the fifth MOSFET TR-PH is relatively small compared to that of the fourth MOSFET TR-CPH. Accordingly, the fifth MOSFET TR-PH may minimize leakage current in a stand-by state.

In the fourth MOSFET TR-CPH, a high voltage may be applied to a pole opposite to an operating voltage in a stand-by state since an operating voltage of the third MOSFET TR-CNH forming the high voltage CMOS device CH together with the fourth MOSFET TR-CPH is relatively high. In the case in which a group IV compound semiconductor layer such as Si—Ge is used as a channel of the fourth MOSFET TR-CPH, a leakage current such as a GIDL current could increase greatly when the transistor is in a stand-by state. However, in this embodiment, the second active region 110N of the semiconductor substrate 110 is used as the channel of the fourth MOSFET TR-CPH to thereby minimize the leakage current.

Moreover, the fifth MOSFET TR-PH operates as a separate switch device. Therefore, a high voltage is not applied to a pole opposite to an operating voltage in a stand-by state, and thus, a leakage current does not increase even though the group IV compound semiconductor layer 120 is used as a channel of the fifth MOSFET TR-PH. In addition, transistor performance may be improved by using the group IV compound semiconductor layer 120 as the channel of the fifth MOSFET TR-PH.

The gate electrode structures of the first through fifth MOSFETs TR-CNL, TR-CPL, TR-CNH, TR-CPH, and TR-PH have respective heights t1, t2, t3, t4, and t9 relative to the main surface of the semiconductor substrate 110. The height t9 may be greater than the height t2, the height t2 may be greater than the height t4, the height t4 may be greater than the height t3, and the height t3 may be greater than the height t1.

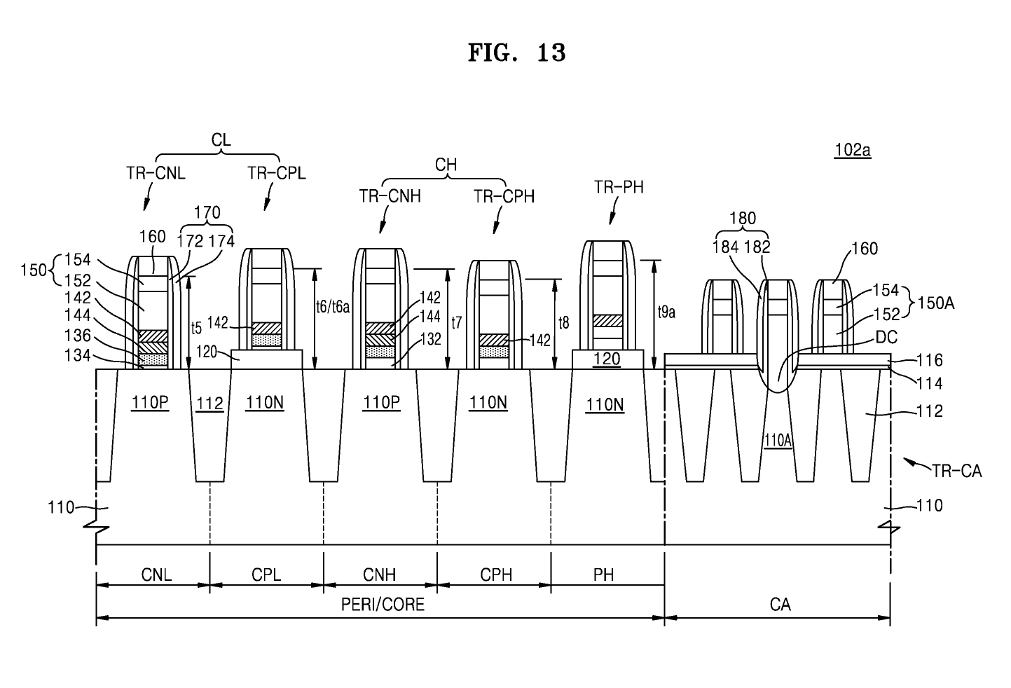

FIG. 13 is a cross-sectional view of another representative embodiment of a semiconductor device 102a according to the inventive concept. Regarding the detailed description of FIG. 13, details overlapping with details described with reference to FIGS. 10 through 12 are omitted.

Referring to FIG. 13, the semiconductor device 102a of this embodiment includes a fifth transistor region PH formed in a peripheral/core region PERI/CORE. That is, the semiconductor device 102a shown in FIG. 13 is similar to the semiconductor device 100a shown in FIG. 11 except that the semiconductor device 102a further includes a fifth MOSFET TR-PH formed in the fifth transistor region PH.

First and second MOSFETs TR-CNL and TR-CPL may form a low voltage CMOS device CL together, third and fourth MOSFETs TR-CNH and TR-CPH may form a high voltage CMOS device CH, and the fifth MOSFET TR-PH may operate as a switch device.

The fifth MOSFET TR-PH may be a PMOSFET. The fifth MOSFET TR-PH has substantially the same structure as the fourth MOSFET TR-CPH of the high voltage CMOS device CH. However, the fourth MOSFET TR-CPH uses a second active region 110N of a semiconductor substrate 110 as a channel, whereas the fifth MOSFET TR-PH uses a group IV compound semiconductor layer 120 as a channel. That is, the semiconductor device 102a may be formed by a manufacturing method that is substantially the same as the method of manufacturing the semiconductor device 100a shown in FIG. 11, except that the group IV compound semiconductor layer 120 is formed also in the fifth transistor region PH, which is a high voltage transistor region, when the group IV compound semiconductor layer 120 is formed in the second transistor region CPL and a stack structure similar to the fourth stack structure of the fourth MOSFET TR-CHP is formed on the group IV compound semiconductor layer 120 formed in the fifth transistor region PH.

The fifth MOSFET TR-PH may be designed so that the absolute value of the threshold voltage of the fifth MOSFET TR-PH is relatively small compared to that of the fourth MOSFET TR-CPH. Accordingly, the fifth MOSFET TR-PH may minimize a leakage current in a stand-by state.

Because the fifth MOSFET TR-PH operates as a separate switch device, a high voltage is not applied to a pole opposite to an operating voltage in a stand-by state and thus, a leakage current does not increase even though the group IV compound semiconductor layer 120 is used as a channel of the fifth MOSFET TR-PH. In addition, transistor performance may be improved by using the group IV compound semiconductor layer 120 as the channel of the fifth MOSFET TR-PH.

The gate electrode structures of the first through fifth MOSFETs TR-CNL, TR-CPL, TR-CNH, TR-CPH, and TR-PH have respective heights t5, t6, t7, t8, and t9a relative to the main surface of the semiconductor substrate 110. The height t9a may be greater than the height t6, the height t6 may be greater than the height t7, and the height t7 may be greater than the height t5 and the height t8.

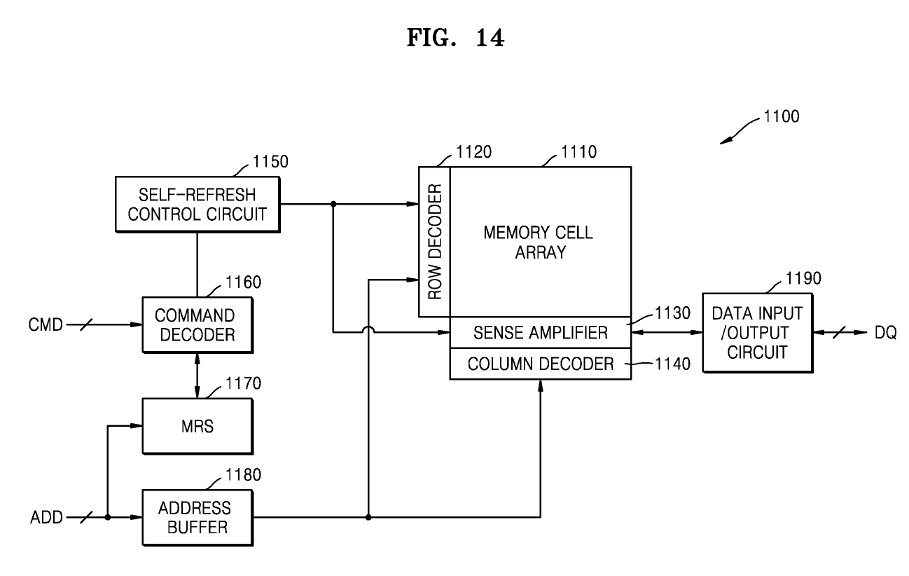

FIG. 14 is a block diagram of a representative embodiment of a semiconductor device 1100 according to the inventive concept.

Referring to FIG. 14, the semiconductor device 1100 includes a memory cell array 1110, a row decoder 1120, a sense amplifier 1130, a column decoder 1140, a self-refresh control circuit 1150, a command decoder 1160, a mode register set/extended mode register set (MRS/EMRS) circuit 1170, an address buffer 1180, and a data input/output circuit 1190.

Memory cells for storing data are arranged in rows and columns in the memory cell array 1110. The plurality of memory cells may be each formed of a cell capacitor and an access transistor. A gate of the access transistor may be connected with a corresponding word line from among a plurality of word lines arranged in the row direction. One of a source and a drain of the access transistor may be connected with a bit line BL or complementary bit line (/BL) arranged in the column direction, and the other may be connected with the cell capacitor. The memory cell array 1110 may be formed in a cell array regions CA in any of the embodiment of FIGS. 10 through 13. Elements other than the memory cell array 1110 may be formed in the peripheral/core region PERI/CORE.

The sense amplifier 1130 detects and amplifies data of the memory cells and stores data in the memory cell. The sense amplifier 30 may be realized as a cross-coupled amplifier connected between the bit line BL and the complementary bit line/BL.

Data DQ input via the data input/output circuit 1190 is written in the memory cell array 1110 based on an address signal ADD, and data DQ read from the memory cell array 10 based on the address signal ADD is output via the data input/output circuit 90. The address signal ADD is input in the address buffer 1180 to designate a memory cell to/from which the data is to be written/read. The address buffer 1180 temporarily stores the address signal ADD input from the outside.

The row decoder 1120 decodes a row address from the address signal ADD output from the address buffer 1180, in order to designate a word line connected with a memory cell to/from which data is to be input/output. That is, the row decoder 1120 decodes the row address output from the address buffer 1180 and enables a corresponding word line in a data writing or reading mode. Also, the row decoder 1120 decodes a row address generated from an address counter and enables a corresponding word line in a self-refresh mode.

The column decoder 1140 decodes a column address from the address signal ADD output from the address buffer 1180, in order to designate a bit line connected with the memory cell to/from which data is to be input/ouput.

The memory cell array 1110 outputs data or writes data from/to the memory cell designated by the row and column addresses.

The command decoder 1160 receives a command signal CMD applied from the outside and decodes the command signal CMD to generate internally a decoded command signal, such as a self-refresh entry command or a self-refresh exit command.

The MRS/EMRS circuit 1170 sets a mode register inside the MRS/EMRS circuit 70 in response to an MRS/EMRS command and an address signal ADD for designating an operation mode of a semiconductor device 1100.

Although not illustrated in FIG. 14, the semiconductor device 1100 may also include a clock circuit for generating a clock signal and a power circuit for receiving a power voltage applied from the outside to generate or distribute an inner voltage.

The self-refresh control circuit 1150 controls a self-refresh operation of the semiconductor device 1100 in response to a command output from the command decoder 1160.

The command decoder 1160 may include an address counter, a timer, and a core voltage generator. The address counter may generate a row address for designating a row address which is to be the subject of the self-refresh operation and apply the generated row address to the row decoder 1120, in response to a self-refresh entry command output from the command decoder 1160. The address counter may end a counting operation in response to a self-refresh exit command output from the command decoder 1160.

The semiconductor device 1100 may exhibit minimal leakage current in transistors in the peripheral/core region PERI/CORE, as described with reference to FIGS. 10 through 13. Accordingly, the semiconductor device 1100 may operate at low power and at high speed.

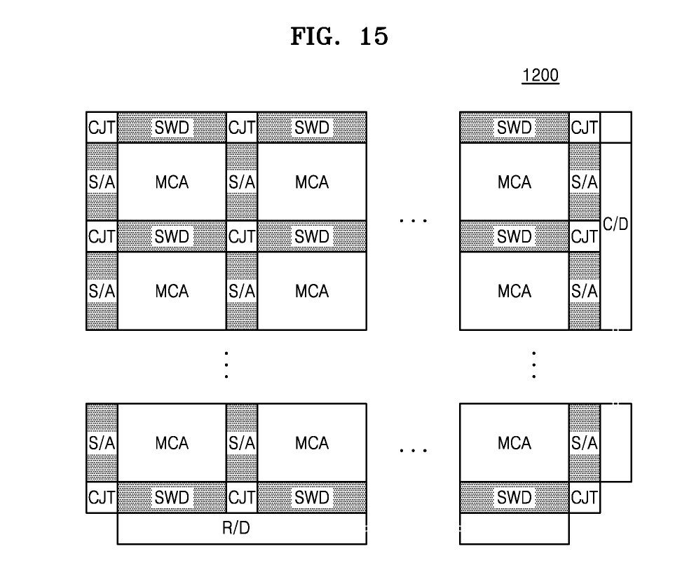

FIG. 15 is a diagram illustrating a layout of a memory core unit of a an embodiment of a semiconductor device according to the inventive concept, and which includes a memory cell array, a sense amplifier, and a core region of the device illustrated in FIG. 14.

Referring to FIG. 15, the memory core unit 1200 of this embodiment includes a plurality of memory cell array blocks MCA. The plurality of memory cell array blocks MCA may form the memory cell array 1110 illustrated in FIG. 14.

A plurality of sub-word line driver blocks SWD may be arranged in a word line direction of the memory cell array blocks MCA, and a plurality of sense amplifier blocks S/A may be arranged in a bit line direction of the memory cell array blocks MCA. A plurality of bit line sense amplifiers constitute the sense amplifier blocks S/A.

Conjunction blocks CJT may be arranged in positions where the sub-word line driver blocks SWD intersect the sense amplifier blocks S/A. Power drivers and ground drivers for driving the bit line sense amplifiers may be alternately arranged in the conjunction blocks CJT.

The memory cell array blocks MCA may be disposed in the cell array region CA shown in FIGS. 10 through 13. Elements other than those constituting the memory cell array blocks MCA may be formed in a core region of the peripheral/core region PERI/CORE corresponding to any of those shown in FIGS. 10 through 13. Elements that have been shown in and described with reference to FIG. 14 but which are not illustrated in FIG. 15 may be formed in the peripheral circuit region of the peripheral/core region PERI/CORE corresponding to any of those shown in FIGS. 10 through 13.

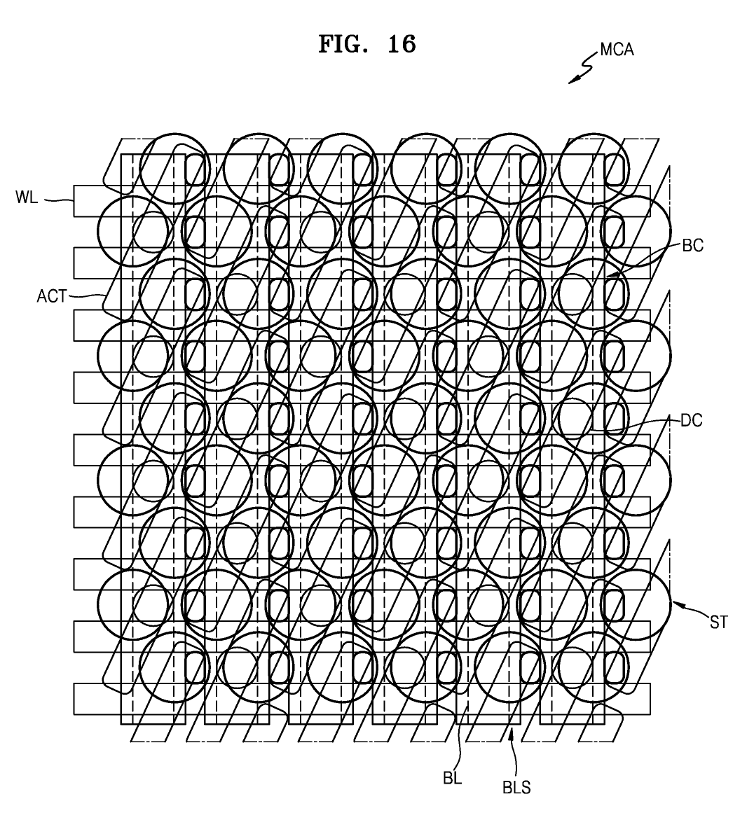

FIG. 16 is a diagram of an example of the layout of each memory cell array block MCA of the device illustrated in FIG. 15.

Referring to FIG. 16, the memory cell array block MCA includes a plurality of active regions ACT. The plurality of active regions ACT may correspond to the active region 110A of any of the cell array regions CA shown in FIGS. 2 through 13. Each of the plurality of active regions ACT may have a substantially elongated island shape so as to have well defined minor and major axes. Each of the plurality of active regions ACT may have a major axis extending diagonally with respect to a first direction. A plurality of word lines WL extend in parallel with one another in a second direction across the plurality of active regions ACT. The plurality of word lines WL may be arranged at equal intervals. On the plurality of word lines WL, a plurality of bit lines BL extend in parallel with one another in the first direction which is perpendicular to the second direction. The plurality of word lines WL may each be a buried gate electrode in the semiconductor substrate 110 of any of the cell array regions CA shown in FIGS. 2 through 13. Each of the plurality of bit lines BL and a bit line spacer layer extending along both sides of the bit line may form a bit line structure BLS. Bit line structures BLS may extend parallel to one another in the first direction. The plurality of bit lines BL may correspond to the bit line electrode layer 150A and the bit line spacer layer may correspond to the bit line spacer 180 in any of the embodiments shown in and described with reference to FIGS. 10 through 13.

The bit lines BL are connected with the active areas ACT through a plurality of direct contacts DC. The active areas ACT may be electrically connected to the direct contacts DC, respectively.

A plurality of buried contacts BC may be formed in a region between adjacent ones of the bit line structures BLS. In an example of this embodiment, the plurality of buried contacts BC are spaced apart from one another in a lengthwise direction of the space between the adjacent bit line structures BLS, that is, the first direction. The plurality of buried contacts BC may have the form of a matrix in which the buried contacts BC are arrayed in the first direction and the second direction. Also, the plurality of buried contacts BC may be spaced at equal intervals in the first direction.

The plurality of buried contacts BC may electrically connect a storage node ST which is a lower electrode of a capacitor to the plurality of active areas ACT. Each of the plurality of active areas ACT may be electrically connected to two buried contacts BC.

A storage node ST, which is a lower electrode of each of a plurality of capacitors, may be electrically connected with the active region ACT. The storage node ST may be electrically connected to the active region ACT via the buried contact BC. A capacitor dielectric (not shown) and an upper electrode (not shown) may be disposed on the storage node ST to form a capacitor together with the storage node ST.

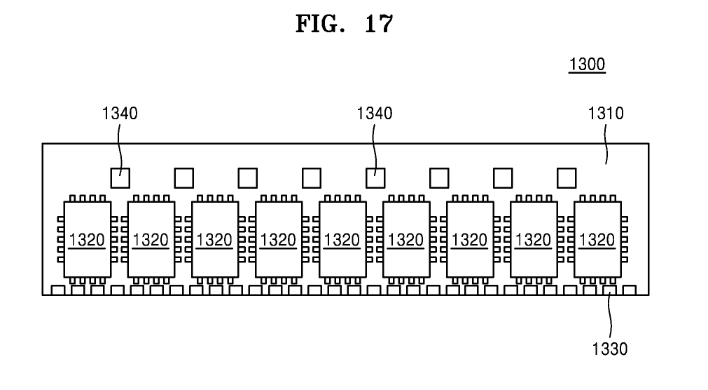

FIG. 17 is a plan view of one example of a memory module 1300 including an embodiment of a semiconductor device according to the inventive concept.

Referring to FIG. 17, the memory module 1300 includes a module substrate 1310 and a plurality of semiconductor chips 1320 attached to the module substrate 1310.

Each of the semiconductor chips 1320 includes a semiconductor device according to the inventive concept. For example, the semiconductor chip 1320 may include any of the semiconductor devices 100, 100a, 102, and 102a of FIGS. 10 through 13.

A connection unit 1330 that may be inserted into a socket of a mother board is disposed on a side of the module substrate 1310. A ceramic decoupling capacitor 1340 is disposed on the module substrate 1310.

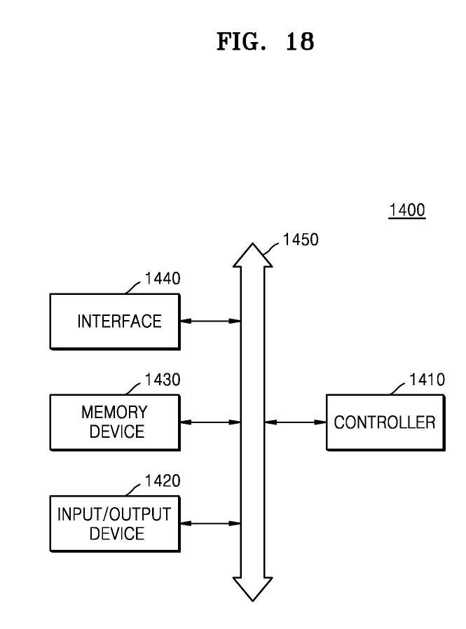

FIG. 18 is a block diagram of an example of a system 1400 including an embodiment of a semiconductor device according to the inventive concept.

Referring to FIG. 18, the system 1400 includes a controller 1410, an input/output device 1420, a memory device 1430, and an interface unit 1440. The system 1400 may be a mobile system or a system that transmits or receives information. For example, the mobile system may be a personal digital assistant (PDA), a portable computer, a web tablet, a wireless phone, a mobile phone, a digital music player, or a memory card. The controller 1410 for controlling an execution program of the system 1400 may be a microprocessor, a digital signal processor, a microcontroller, or the like. The input/output device 1420 may be used to input or output data of the system 1400. The system 1400 may be connected to an external device, for example, a personal computer or a network and may exchange data with the external device, by using the input/output device 1420. The input/output device 1420 may be, for example, a keypad, a keyboard, or a display device.

The memory device 1430 may store code and/or data for operating the controller 1410, or store data processed by the controller 1410. The memory device 1430 includes a semiconductor device according to the inventive concept. For example, the memory device 1430 may include any of the semiconductor devices 100, 100a, 102, and 102a of FIGS. 10 through 13.

The interface unit 1440 may be a data transmission path between the system 1400 and an external device. The controller 1410, the input/output device 1420, the memory device 1430, and the interface unit 1440 may communicate with one another via a bus 1450. The system 1400 may constitute a solid-state drive (SSD) and/or may be the electronic system of a mobile phone, an MP3 player, a navigation system, a portable multimedia player (PMP), or a household appliance.

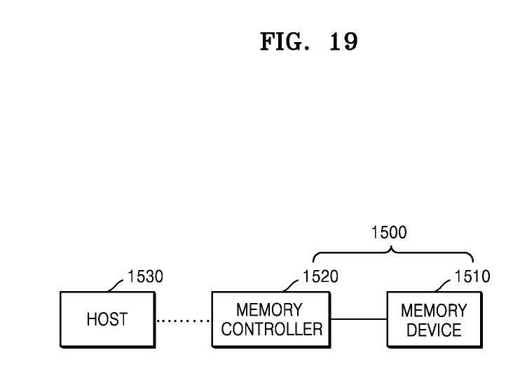

FIG. 19 is a block diagram of an example of a memory card 1500 including an embodiment of a semiconductor device according to the inventive concept.

Referring to FIG. 19, the memory card 1500 includes a memory device 1510 and a memory controller 1520.

The memory device 1510 may store data. In some embodiments, the memory device 1510 may have nonvolatile characteristics, i.e., the memory device 1510 may retain stored data even when power supply is cut off The memory device 1510 includes a semiconductor device according to the inventive concept. For example, the memory device 1510 may include any of the semiconductor devices 100, 100a, 102, and 102a of FIGS. 10 through 13.

The memory controller 1520 may read data from the memory device 1510 or write data to the memory device 1510 in response to a read/write request of a host 1530.

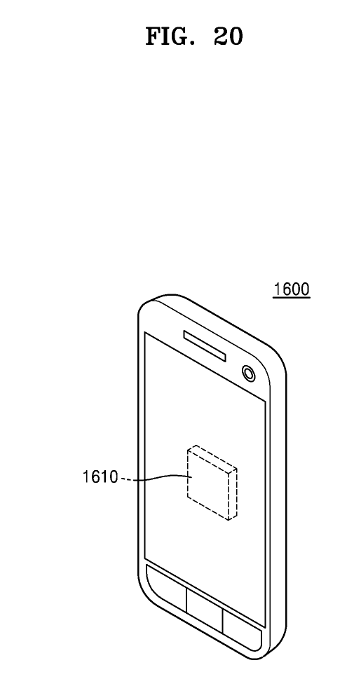

FIG. 20 is a perspective view of an electronic device which may employ a semiconductor device 1610 according to the inventive concept. In particular, FIG. 20 illustrates a mobile phone 1600 and the mobile phone may comprise the electronic system 1400 of FIG. 18. The semiconductor device 1610 may be any one of the semiconductor devices 100, 100a, 102, and 102a of FIGS. 10 through 13. The semiconductor device 1610 may be a mobile DRAM semiconductor device.

Accordingly, the mobile phone 1600 may operate at low power and at high speed, and thus may be compact, operate for a long time before it has to be recharged, and exhibit high performance.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

What is claimed is:

1. A semiconductor device comprising:
a semiconductor substrate having a first transistor region and a second transistor region;
a first metal-oxide-semiconductor field effect transistor (MOSFET) comprising a first gate insulating layer structure and a first gate electrode structure, wherein the first gate insulating layer structure and the first gate electrode structure are disposed on the first transistor region of the semiconductor substrate; and
a second MOSFET comprising a group IV compound semiconductor layer, a second gate insulating layer structure, and a second gate electrode structure, wherein the group IV compound semiconductor layer is disposed on the second transistor region of the semiconductor substrate, and the second gate insulating layer structure and the second gate electrode structure are disposed on the group IV compound semiconductor layer, and
wherein each of the first and second gate insulating layer structures comprises a high-k dielectric layer.

2. The semiconductor device of claim 1, wherein the first gate insulating layer structure further comprises a first dielectric layer having a dielectric constant less than that of the high-k dielectric layer, and the high-k dielectric layer of the first gate insulating layer structure is stacked on the first dielectric layer, and
wherein the second gate insulating layer structure further comprises a second dielectric layer thinner than the first dielectric layer and having a dielectric constant greater than that of the second dielectric layer, and the high-k dielectric layer of the second gate insulating layer structure is stacked on the second dielectric layer.

3. The semiconductor device of claim 2, wherein the first dielectric layer contacts the semiconductor substrate in the first transistor region, and the second dielectric layer contacts the group IV compound semiconductor layer in the second transistor region.

4. The semiconductor device of claim 1, wherein an absolute value of an operating voltage of the first MOSFET is greater than that of an operating voltage of the second MOSFET.

5. The semiconductor device of claim 1, wherein the first MOSFET and the second MOSFET are PMOSFETs.

6. The semiconductor device of claim 1, wherein part of the semiconductor substrate provides the channel of the first MOSFET, and part of the group IV compound semiconductor layer provides the channel of the second MOSFET.

7. The semiconductor device of claim 1, wherein the semiconductor substrate has a third transistor region and a fourth transistor region, and
the semiconductor device further comprises:
a third MOSFET comprising a third gate insulating layer structure and a third gate electrode structure, wherein the third gate insulating layer structure and the third gate electrode structure are disposed on the third transistor region of the semiconductor substrate; and
a fourth MOSFET comprising a fourth gate insulating layer structure and a fourth gate electrode structure, wherein the fourth gate insulating layer structure and the fourth gate electrode structure are disposed on the fourth transistor region of the semiconductor substrate, and
wherein a conductivity of the semiconductor substrate in the first and second transistor regions is different from that of the semiconductor substrate in the third and fourth transistor regions, and each of the third and fourth gate insulating layer structures comprises a high-k dielectric layer.

8. The semiconductor device of claim 7, wherein the third gate insulating layer structure further comprises a third dielectric layer, the high-k dielectric layer of the third gate insulating structure is stacked on the third dielectric layer, and the high-k dielectric layer of the third gate insulating structure is of material having a dielectric constant greater than that of the third dielectric layer, and
the fourth gate insulating layer structure further comprises a fourth dielectric layer thinner than the third dielectric layer and having a dielectric constant greater than that of the fourth dielectric layer, and the high-k dielectric layer of the fourth gate insulating structure is stacked on the fourth dielectric layer.

9. The semiconductor device of claim 7, wherein the height of the second gate electrode structure is greater than the height of the fourth gate electrode structure, the height of the fourth gate electrode structure is greater than the height of the third gate electrode structure, and the height of the third gate electrode structure is greater than the height of the first gate electrode structure, all relative to a main surface of the semiconductor substrate.

10. The semiconductor device of claim 7, wherein the height of the second gate electrode structure is greater than the height of the third gate electrode structure, and the height of the third gate electrode structure is greater than the height of the first gate electrode structure and the height of the fourth gate electrode structure, all relative to a main surface of the semiconductor substrate.

11. The semiconductor device of claim 7, wherein the semiconductor substrate has a fifth transistor region, the first MOSFET and the third MOSFET constitute one complementary metal-oxide-semiconductor (CMOS) device, and the second MOSFET and the fourth MOSFET constitute another CMOS device, and
the semiconductor device further comprises:
a fifth MOSFET comprising a group IV compound semiconductor layer of the same material as that of the second MOSFET, and a gate insulating layer structure and gate electrode structure of the same materials as the first MOSFET, respectively, wherein the group IV compound semiconductor layer of the fifth MOSFET is disposed on the fifth transistor region of the semiconductor substrate, the gate insulating layer structure and the gate electrode structure of the fifth MOSFET are disposed on the group IV compound semiconductor layer of the fifth MOSFET, and the fifth MOSFET constitutes a switch.

12. A semiconductor device comprising:
a semiconductor substrate having a cell array region and a peripheral/core region;
a cell transistor at the cell array region;
a bit line electrode electrically connected to the cell transistor;
a first metal-oxide-semiconductor field effect transistor (MOSFET) comprising a first gate insulating layer structure and a first gate electrode structure, wherein the first gate insulating layer structure is disposed on the peripheral/core region of the semiconductor substrate, and the first gate electrode structure is disposed on the first gate insulating structure; and
a second MOSFET comprising a group IV compound semiconductor layer, a second gate insulating layer structure, and a second gate electrode structure, wherein the group IV compound semiconductor layer is disposed on the peripheral/core region of the semiconductor substrate, and the second gate insulating layer structure and the second gate electrode structure are disposed on the group IV compound semiconductor layer, and
wherein each of the first and second gate insulating layer structures comprises a high-k dielectric layer, and the bit line electrode comprises the same material as at least a portion of each of the first and second gate electrode structures.

13. The semiconductor device of claim 12, wherein the first gate insulating layer structure is thicker than the second gate insulating layer structure.

14. The semiconductor device of claim 12, wherein the first MOSFET constitutes an inverter chain circuit or a sense amplifier.

15. The semiconductor device of claim 12, wherein the second MOSFET is constitutes a sub-word line driver circuit or a row decoder circuit.

16. A semiconductor device comprising:
a first complementary metal-oxide-semiconductor field effect transistor (CMOS) including a p-type metal-oxide-semiconductor field effect transistor (PMOS) having a channel region of first semiconductor material, a first gate insulating structure of dielectric material disposed directly on the channel region, and a first electrically conductive gate structure disposed directly on the first gate insulating structure; and
a second CMOS including a second PMOS having a channel region of second semiconductor material in which holes have greater mobility than the holes have in the first semiconductor material constituting the channel region of the first PMOS, a second gate insulating structure of dielectric material disposed directly on the channel region of the second PMOS, and a second electrically conductive gate electrode structure disposed directly on the second gate insulating structure, and
the first gate insulating structure is thicker than the second gate insulating structure, and
the operating voltage of the first CMOS is higher than that of the second CMOS.

17. The semiconductor device of claim 16, wherein the first semiconductor material is Si, and the second semiconductor material is SiGe.

18. The semiconductor device of claim 16, wherein the first gate insulating structure comprises a first gate dielectric of material selected from the group consisting of SiO, SiN, SiON and ONO and disposed directly on the channel region of the first PMOS, the second gate insulating structure comprises a second gate dielectric of material selected from the group consisting of SiO, SiN, SiON and ONO and disposed directly on the channel region of the second PMOS, and the first gate dielectric is thicker than the second gate dielectric.

19. The semiconductor device of claim 18, wherein the first gate insulating structure further comprises a high-k dielectric having a greater dielectric constant than and disposed on the first gate dielectric, the second gate insulating structure further comprises a high-k dielectric having a greater dielectric than and disposed on the second gate dielectric, and the thicknesses of the high-k dielectrics are equal.

20. The semiconductor device of claim 16, further comprising insulating material disposed directly on respective upper surfaces of the first electrically conductive gate structure and the second electrically conductive gate structure, and
wherein the channel region of the second PMOS is an epitaxial layer disposed on the first semiconductor material, and
the height of the second PMOS, as measured from a surface of the first semiconductor material to the upper surface of the first electrically conductive gate structure, is greater than the height of the second PMOS as measured from said surface of the first semiconductor material to the upper surface of the second electrically conductive gate structure.
